(19) United States
(12) Patent Application Publication
(10) Pub. No.: US 2026/0324331 A1
(43) Pub. Date: Oct. 15, 2026

(54) METHOD OF SEPARATING A SEMICONDUCTOR DEVICE FROM A SUBSTRATE

(71) Applicant: PORO TECHNOLOGIES LTD, Cambridge, Cambridgeshire (GB)

(72) Inventors: Tongtong ZHU, Cambridge, Cambridgeshire (GB); Kunal KASHYAP, Cambridge, Cambridgeshire (GB); Jia-Liang TU, Cambridge, Cambridgeshire (GB); Kai-Jyun HUANG, Cambridge, Cambridgeshire (GB)

(21) Appl. No.: 19/109,367

(22) PCT Filed: Sep. 8, 2023
(86) PCT No.: PCT/GB2023/052330

§ 371 Date: Mar. 6, 2025

(30) Foreign Application Priority Data
Sep. 8, 2022 (GB) 2213149.4

(51) Int. Cl. H10P 54/30; B23K 26/55; B23K 101/40; H10D 30/01; H10H 20/01; H10P 32/10; H10P 32/14; H10P 54/20; H10P 54/50; H10P 54/92; H10P 54/94

(52) U.S. Cl. CPC H10P 54/30; B23K 26/55; H10D 30/015; H10H 20/019; H10P 32/1406; H10P 32/174; H10P 54/20; H10P 54/52; H10P 54/92; H10P 54/94; B23K 2101/40

(57) ABSTRACT

A method of separating a semiconductor device from a substrate comprises the steps of: providing a semiconductor structure comprising a semiconductor device, a substrate, and a porous layer of semiconductor material between the semiconductor structure and the substrate; creating a weakened zone in the semiconductor structure between the semiconductor device and the substrate; cleaving the semiconductor structure along the weakened zone; and separating the semiconductor device from the substrate. The weakened zone is created in the porous layer of semiconductor material, or in a buffer layer of semiconductor material positioned between the substrate and the porous layer. A semiconductor structure comprises a porous layer of semiconductor material and a semiconductor device bonded to a carrier wafer, in which the semiconductor device is positioned between the porous layer and the carrier wafer.

The invention relates to a method of separating a semiconductor device from a substrate. In particular the invention relates to a method of separating optoelectronic semiconductor devices, or high electron mobility transistor devices, from substrates comprising a porous layer of semiconductor material.

### BACKGROUND

III-V semiconductor materials are of particular interest for semiconductor device design, in particular the family of III-nitride semiconductor materials.

“III-V” semiconductors include binary, ternary and quaternary alloys of Group III elements, such as Ga, Al and In, with Group V elements, such as N, P, As and Sb, and are of great interest for a number of applications, including electronics and optoelectronics.

Of particular interest is the class of semiconductor materials known as “III-nitride” materials, which includes gallium nitride (GaN), indium nitride (InN) and aluminium nitride (AlN), along with their ternary and quaternary alloys. (Al, In)GaN is a term encompassing AlGaN, InGaN and GaN. III-nitride materials have not only achieved commercial success in solid-state lighting and power electronics, but also exhibit particular advantages for quantum light sources and light-matter interaction.

While a variety of III-nitride materials are commercially interesting, Gallium nitride (GaN) is widely regarded as one of the most important new semiconductor materials, and is of particular interest for a number of applications.

The present invention will be described primarily by reference to GaN and InGaN, but may advantageously be applicable to alternative III-nitride material combinations.

It is known that the introduction of pores into bulk III-nitrides, such as GaN can profoundly affect its material properties (optical, mechanical, electrical, and thermal, etc.). The possibility of tuning a wide range of material properties of GaN and III-nitrides semiconductors by altering its porosity therefore makes porous GaN of great interest for optoelectronic applications.

The present inventors have also found that by using porous III-nitride material as a substrate, or template, for overgrowth of additional semiconductor layers and semiconductor devices, beneficial properties such as strain relaxation may be imparted to the overgrown devices by the porous layer. Following overgrowth of the desired semiconductor devices, however, it may be desirable to remove the semiconductor devices from the porous template, and to transfer the semiconductor devices to another carrier for fabrication into an electronic or optoelectronic device. It is an aim of the present invention to facilitate the safe and reliable removal of a semiconductor device from a substrate on which it has been grown.

In the present invention, regions or layers of semiconductor material may be porosified by electrochemical etching as set out in international patent applications PCT/GB2017/052895 (published as WO2019/063957) and PCT/GB2019/050213 (published as WO2019/145728).

### PROBLEM TO BE SOLVED

As part of semiconductor device fabrication, it is desirable to separate semiconductor devices from the substrates on which they have been grown, and to transfer them onto a separate wafer for further processing. Semiconductor devices of different types may be transferred onto a shared carrier wafer before processing the shared wafer into a finished product. For example it is frequently desirable to combine multiple different LED types, which emit at different peak emission wavelengths, onto a single carrier wafer for fabrication into a display device.

Conventionally, however, this step of transferring different semiconductor devices from their original substrates onto a shared wafer has several drawbacks. Firstly, different types of semiconductor devices are frequently formed from different materials, which in turn require different lift-off processing. For example red and blue-green LEDs are typically grown from different semiconductor materials, which require different lift-off processes to separate them from the substrates on which they are grown. This increases the cost and difficulty of device fabrication. Secondly, the lift-off processes that are conventionally used to separate devices from their original substrates often damages the epitaxial layers (epi-layers) of the semiconductor devices. Damage caused by lift-off processes is thus a major contributor to the loss of yield in semiconductor device fabrication, which increases the cost of manufacturing.

To simplify LED manufacturing processes and reduce mass production cost, Poro Technologies has released LEDs featuring embedded nanoporous architecture, which enables GaN-based LEDs to output full color range. These LEDs are described, for example, in international patent applications PCT/GB2021/050152 (published as WO2021/148808) and PCT/GB2021/052020 (published as WO2022/029434).

### SUMMARY OF INVENTION

In a first aspect of the present invention there is provided a method of separating a semiconductor device from a substrate, the method comprising the steps of: providing a semiconductor structure comprising a semiconductor device, a substrate, and a porous layer of semiconductor material between the semiconductor structure and the substrate. The method comprises the steps of creating a weakened zone in the semiconductor structure between the semiconductor device and the substrate; cleaving the semiconductor structure along the weakened zone; and separating the semiconductor device from the substrate. The weakened zone may be created either in the porous layer of semiconductor material, or in a buffer layer of semiconductor material positioned between the substrate and the porous layer.

The weakened zone may be created in the porous layer of semiconductor material, so that cleaving the semiconductor structure along the weakened zone cleaves the porous layer of semiconductor material. This may be accomplished in several ways, as discussed below.

Alternatively, if the semiconductor structure comprises a buffer layer of semiconductor material positioned between the substrate and the porous layer, the weakened zone may be created in this buffer layer of semiconductor material. The step of cleaving the semiconductor structure along the weakened zone thus cleaves the buffer layer of semiconductor material instead of the porous layer. In this embodiment, the porous layer may advantageously act as a protective layer which shields the semiconductor device from any stresses and forces created during the cleaving and separation steps, and prevents cracks created during cleaving from propagating into the epitaxial structure of the semiconductor device.

The porous layer of semiconductor material is preferably a porous layer of III-nitride material. The porous layer is preferably a porous layer of semiconductor material which extends laterally throughout the semiconductor structure.

Preferably the porous layer is continuously porous, for example formed from a continuous layer of porous III-nitride material. Alternatively the porous layer may be a layer of semiconductor material containing one or more porous regions, as well as one or more non-porous regions, such that the porous material does not extend continuously throughout a whole layer of the semiconductor structure.

The porous layer is preferably a layer of porous III-nitride material, for example a porous layer of GaN, InGaN, AlGaN, or InAlGaN.

The semiconductor structure is preferably formed entirely from III-nitride material, for example GaN, InGaN, AlGaN, or InAlGaN.

The weakened zone preferably comprises a weakened layer which extends laterally through a layer of the semiconductor structure. This may advantageously help to ensure that the structure is cleaved cleanly through the weakened zone, to minimise the likelihood of cracks propagating vertically through the semiconductor structure into layers other than the layer containing the weakened zone.

The skilled person will understand that in this context “laterally” refers to the plane of the semiconductor structure which extends parallel to the plane of the substrate, while in this context “vertically” refers to the direction orthogonal to the plane of the substrate, such that sequentially-deposited layers of the semiconductor structure are stacked vertically upon one another as the structure grows upwards from the substrate.

The substrate may be any conventional semiconductor substrate suitable for overgrowth of III-nitride semiconductor structures. For example the substrate may be a wafer of Silicon, Sapphire, SiC, GaN, or β-Ga2O3. The crystal orientation of the substrates can be polar, semi-polar or non-polar orientation. The substrate thickness may typically vary between 100 μm and 1500 μm.

The semiconductor structure may optionally contain one or more buffer layers of semiconductor material positioned between the substrate and the porous layer. Where it is present, the buffer layer of semiconductor material is preferably a non-porous layer of semiconductor material which extends laterally throughout the semiconductor structure and separates the porous layer from the substrate. The one or more buffer layers can be formed from any III-nitride semiconductor material, for example any combination of (Al,In)GaN alloys. Preferably the one or more buffer layers are formed from undoped III-nitride material, or non-intentionally-doped III-nitride material.

In alternative embodiments the semiconductor structure may not comprise any buffer layers between the porous layer and the substrate. In this embodiment, the porous layer may be in contact with the substrate, and the weakened zone will be created in the porous layer of semiconductor material.

The semiconductor structure may optionally comprise one or more non-porous layers of semiconductor material arranged between the porous layer and the semiconductor device. The number, composition and structure of these layers may be varied to suit the semiconductor device.

The step of separating the semiconductor device from the substrate is preferably a “lift-off” step in which the semiconductor device (and optionally any additional portions of the semiconductor structure which remain attached to the device after the structure is cleaved) is lifted off the substrate (and optionally any additional portions of the semiconductor structure which remain attached to the substrate after the structure is cleaved).

The method of the present invention has the benefit that during cleaving and lift-off, the porous layer in the semiconductor structure acts as a structural protection layer and a compliant layer, as the porosity of the porous layer increases the ability of the porous layer to flex and absorb stresses and strains applied to the semiconductor structure during cleaving and separation. This advantageously reduces epi-layer damage to the semiconductor devices, and thus results in a better yield of end-products. The porous layer also imparts a variety of benefits to the overgrown semiconductor devices during epitaxial growth, which are inherited and retained in the semiconductor devices after they have been separated from the substrate, even if the porous layer is cleaved and/or completely removed from the semiconductor device.

The step of cleaving the semiconductor structure through the weakened zone may comprise mechanically impacting the semiconductor structure to initiate a fracture.

Alternatively, the creation of the weakened zone may initiate a fracture which propagates through the semiconductor structure to cleave the structure without a need for any mechanical initiation.

Following the step of creating the weakened zone in the semiconductor structure, the step of cleaving and separating the semiconductor structure may comprise applying a mechanical force. For example, the parts of the semiconductor structure on opposite sides of the weakened zone may be mechanically gripped and pulled away from one another.

The semiconductor structure may preferably be bonded to a carrier wafer so that the semiconductor device and the porous layer are positioned between the carrier wafer and the substrate.

The method preferably comprises the step of bonding the semiconductor device to a carrier wafer prior to forming the weakened zone in the semiconductor structure, and/or prior to cleaving the semiconductor structure, so that the semiconductor device remains bonded to the carrier wafer when the semiconductor device is separated from the substrate. This helps to ensure that the semiconductor devices are mechanically supported during cleaving and separation, and allows them to be securely removed from the substrate after the cleaving has taken place. The carrier wafer may be a temporary carrier wafer, or alternatively the carrier wafer may be a substrate comprising control circuitry for processing into a device.

### Laser Lift-Off

The weakened zone may be created by laser lift-off (LLO). This may comprise the steps of directing a laser into the semiconductor structure through the substrate, focusing the laser at a predetermined depth in the semiconductor structure, and melting semiconductor material at the focal point of the laser. Melting the semiconductor material creates a weakened zone at a predetermined depth in the semiconductor structure (for example in a selected layer of the structure), which may then be easily and cleanly cleaved.

The step of cleaving may be carried out using the laser, for example by cutting through the weakened zone completely using the laser.

Laser-lift off is known in the art in industrial LED production. In a conventional approach used today, a UV laser with pulse width in the nanosecond regime is directed to the backside of the wafer, through the transparent substrate. At high pulse energies, the laser induces decomposition of GaN at the substrate/GaN interface into metallic gallium and gaseous nitrogen which causes subsequent detachment of the GaN layer from the substrate.

In order to create a weakened zone which extends laterally throughout the semiconductor structure to encourage clean cleaving, the laser is preferably focused at a plurality of positions across the semiconductor structure, at the same depth in the structure. For example the laser may be focused sequentially at a plurality of lateral positions throughout the same layer of the semiconductor structure, so as to melt semiconductor material at a plurality of lateral positions. Melting material at a plurality of positions throughout the layer acts to weaken the entire layer, so that the combined effect of many melted spots makes the entire layer into a weakened zone of the structure.

In a first preferred embodiment of the invention, the weakened zone is created in the porous layer of the semiconductor structure by laser lift-off. The method may thus comprise the step of focusing the laser in the porous layer, and melting semiconductor material contained in the porous layer of semiconductor material. Melting semiconductor material creates a weakened zone in the porous layer of the semiconductor structure.

If the porous layer is adjacent to the substrate in the semiconductor structure, the laser may be focused in the porous layer, or at an interface between the porous layer and the substrate. Alternatively the laser may be focused at an interface between the porous layer and a buffer layer of semiconductor material that is positioned between the substrate and the porous layer.

As described above, the semiconductor structure may comprise one or more buffer layers of semiconductor materials positioned between the porous layer and the substrate.

In a second preferred embodiment of the invention, the weakened zone is created in a buffer layer of the semiconductor structure by laser lift-off. The method may comprise the step of focusing the laser in a buffer layer of semiconductor material that is positioned between the substrate and the porous layer.

The method may comprise the step of focusing the laser in the buffer layer.

The buffer layer may be a layer of undoped semiconductor material positioned between the substrate and the porous layer. Preferably the buffer layer is positioned adjacent to the substrate, and the method may comprise the step of focusing the laser at an interface between the buffer layer and the substrate.

When the weakened zone is created in the buffer layer between the porous layer and the substrate, cleaving the semiconductor structure along the weakened zone creates a fracture in the buffer layer. In this embodiment, the porous layer is positioned between the fracture and the semiconductor device, and the porous layer advantageously acts as a “crack-stop” layer which confines the fracture to the buffer layer and prevents the fracture from propagating vertically through the semiconductor structure. In this embodiment, the porous layer remains attached to the semiconductor device after separation, and the porous layer may act as a compliant layer which manages the stress on the semiconductor device after separation from the substrate.

### Ion-Implantation

In a third preferred embodiment, the weakened zone may be created by implanting dopant ions into a layer of semiconductor material. The implanted ions create an additional level of atomic disorder in the layer of semiconductor material by displacing some of the atoms in the crystal structure of that layer. This may advantageously weaken the implanted layer, making it more easily and uniformly cleavable.

The dopant ions may preferably be selected from the list: H+, N+, Ga+, O+, Si+, Mg+, C+.

The method may comprise the step of implanting dopant ions by ion bombardment, for example by bombarding the layer of the semiconductor structure with an ion beam (high energy or low energy-keV-MeV). Alternative methods of ion implantation are also known in the art and may be used to implant dopant ions into the semiconductor structure to create the weakened zone.

The dopant ions are preferably implanted into the semiconductor structure during manufacture of the semiconductor structure, before the semiconductor device has been overgrown.

The weakened zone may be created in the porous layer by implanting dopant ions into the porous layer of semiconductor material. Ions may be implanted into the porous layer after the porous layer has been formed on the substrate, so that the ion-implanted porous layer becomes the weakened zone of the structure. Further layers of semiconductor material and the semiconductor device structure may then be overgrown over the ion-implanted porous layer.

Alternatively, ions may be implanted into a non-porous buffer layer, so that the semiconductor structure contains an ion-implanted non-porous buffer layer which acts as the weakened zone of the semiconductor structure. The ion-implanted non-porous buffer layer is preferably provided between the porous layer and the substrate. Optionally ions may be implanted into a non-porous buffer layer before the porous layer of the semiconductor structure is formed. Further layers of semiconductor material and the semiconductor device structure may then be overgrown over the ion-implanted non-porous buffer layer and the porous layer.

The method may thus comprise the steps of providing a semiconductor structure by: implanting dopant ions into a layer of semiconductor material on a substrate to create a weakened zone, and forming a semiconductor device over the ion-implanted layer. The method may then comprise the steps of cleaving the semiconductor structure along the weakened zone, and separating the semiconductor device from the substrate.

The step of ion-implantation to form the weakened zone may preferably be carried out during manufacture of the semiconductor structure, before the semiconductor device has been formed. The method may thus comprise the steps of providing a semiconductor structure by: implanting dopant ions into a layer of semiconductor material on a substrate to create a weakened zone, and forming a semiconductor device over the ion-implanted layer. The method may then comprise the steps of cleaving the semiconductor structure along the weakened zone, and separating the semiconductor device from the substrate.

The method may comprise the steps of providing a semiconductor structure by: implanting dopant ions into a porous layer of semiconductor material on a substrate to create a weakened zone in the porous layer, and forming a semiconductor device over the ion-implanted porous layer. The method may then comprise the steps of cleaving the semiconductor structure along the weakened zone, and separating the semiconductor device from the substrate.

### Thermal Gradient

In a fourth preferred embodiment of the present invention, the weakened zone is created in the porous layer by creating a thermal gradient across the porous layer, the direction of the thermal gradient being orthogonal to the plane of the porous layer. By making one side of the porous layer hotter than the other, the semiconductor material on the hotter side may be caused to expand, while the semiconductor material on the cooler side may be caused to contract. This difference in thermal expansion and contraction across the porous layer may in turn create a stress in the porous layer which initiates a fracture that propagates through the porous layer to cleave the semiconductor structure.

The thermal gradient may be created by applying a temperature difference between the semiconductor device and the substrate, or between a substrate-side and a device-side of the porous layer.

The method may comprising the step of applying a thermal gradient of at least 50 degrees centigrade between the semiconductor device and the substrate, or at least 60, or 70, or 80, or 90, or 100 degrees centigrade between the semiconductor device and the substrate.

The method may comprising the step of applying a thermal gradient of at least 50 degrees centigrade per um between the semiconductor device and the substrate, or at least 60, or 70, or 80, or 90, or 100 degrees centigrade per um between the semiconductor device and the substrate.

### Post-Separation Steps

Once the semiconductor structure has been cleaved through the weakened zone and the semiconductor device has been separated from the substrate, the method may comprise additional steps to process the separated semiconductor device into an end product.

The step of cleaving creates a cleaved surface connected to the semiconductor device (usually via one or more layers of the semiconductor structure) and another cleaved surface connected to the substrate (usually via one or more layers of the semiconductor structure). The cleaved surfaces are formed by the cleaved remnants of the porous layer if the weakened zone was formed in the porous layer, or by the cleaved surfaces of a buffer layer if the structure was cleaved through a buffer layer.

As the cleaving process typically forms a non-uniform crack or fracture through the semiconductor structure, the cleaved surfaces are typically rough after the structure has been separated. It is typically desirable, therefore, to flatten the cleaved surfaces prior to further processing.

The method may additionally comprise the step of flattening the cleaved surface connected to the semiconductor device after the semiconductor device has been separated from the substrate. The cleaved surface typically forms part of on the layer of the semiconductor structure which was cleaved, or the layer of the semiconductor structure which was adjacent to the layer of the semiconductor structure which was cleaved (as cleaving may occur along an interface between layers). For example the cleaved surface may be a remaining portion of the porous layer which is connected, optionally via intermediate layers, to the semiconductor device.

The method may additionally comprise the step of flattening the cleaved surface connected to the substrate. For example the cleaved surface may be flattened and the flattened substrate may be re-used as a template for overgrowth of semiconductor material. This may advantageously reduce the environmental impact of device processing and reduce costs.

The cleaved surface(s) may be flattened by chemical-mechanical (CMP) polishing or etching.

### Alternative Method

According to a third aspect of the present invention there is provided a method of separating a semiconductor device from a substrate, the method comprising the steps of:
providing a semiconductor structure comprising a semiconductor device, a substrate, and a porous layer of semiconductor material between the semiconductor structure and the substrate;
bonding the semiconductor structure to a carrier wafer so that the semiconductor device and the porous layer are positioned between the carrier wafer and the substrate; and
removing the substrate from the semiconductor structure by polishing, lapping, thinning, wet etching or dry etching the substrate.

The substrate may preferably be a silicon substrate.

In this case, the porous layer can act as an etch stop, a compliant layer, and a supportive layer during or after the separation.

### Semiconductor Devices

The semiconductor device may be a conventional semiconductor device which has been overgrown on a semiconductor template comprising the substrate and the porous region, and preferably one or more non-porous layers of semiconductor material positioned over the porous region. The epitaxial design of such devices are well known in the art and the present invention is not limited to any specific device type, as any type of semiconductor device may be separated from a substrate using the method of the present invention.

The semiconductor device may be an optoelectronic semiconductor device, such as a light-emitting diode (LED) or a vertical cavity surface emitting laser (VCSEL). Alternatively the semiconductor device may be an electronic or electrical component, such as a high electron mobility transistor (HEMT) or a radio frequency (RF) device.

According to a third aspect of the present invention there is provided a semiconductor structure comprising a porous layer of semiconductor material and a semiconductor device bonded to a carrier wafer, in which the semiconductor device is positioned between the porous layer and the carrier wafer. The semiconductor device preferably comprises an active region, for example a light-emitting active region, which is positioned between the porous layer and the carrier wafer.

Preferably the porous layer of semiconductor material forms an outermost surface of the structure, on the opposite side of the active region from the carrier wafer. Alternatively, a buffer layer of semiconductor material may form the outermost surface of the structure, with the porous layer being positioned between the outermost buffer layer and the active region of the semiconductor device.

The semiconductor structure is preferably the product of the method of the first aspect of the invention or the second aspect of the invention. Thus following the separation of the semiconductor device from the original substrate on which the device was grown, the device is preferably bonded to a carrier wafer in a “flip-chip” configuration, with the cleaved surface now forming the outermost surface of the structure on the opposite side from the carrier wafer.

If the structure has been cleaved through the porous layer, a portion of the porous layer may remain connected to the semiconductor device and form the outermost surface of the resulting semiconductor structure.

If the structure has been cleaved through a non-porous buffer layer between the porous layer and the substrate, the porous layer may remain connected to the semiconductor device, and one or more buffer layers may form the outermost surface of the resulting semiconductor structure. Alternatively, if the cleaved buffer layer has been removed during cleaving and optionally during subsequent etching/polishing, the porous layer may form the new outermost surface of the structure.

The semiconductor structure may comprise one or more non-porous layers of semiconductor material arranged between the porous layer and the active region of the semiconductor device.

The semiconductor device may be an optoelectronic semiconductor device, such as a light-emitting diode (LED) or a vertical cavity surface emitting laser (VCSEL). Alternatively the semiconductor device may be an electronic or electrical component, such as a high electron mobility transistor (HEMT) or a radio frequency (RF) device.

In particularly preferred embodiments the semiconductor device may be an LED, or a mini-LED, or a micro-LED, or a nano-LED. The LED may comprise a light-emitting region which preferably comprises a multiple quantum well (MQW) containing a plurality of quantum wells (QWs), or quantum dots, quantum wires, or other quantum nanostructures.

The light-emitting region, and/or the LED, may have lateral dimensions (width and length) of greater than 100 μm and less than 300 μm. In this case, the LED may be termed a “mini-LED”. In preferred embodiments, the mini-LED may be square or circular or square with circular corners and have dimensions such as 300 μm×300 μm, 200 μm×200 μm, 100 μm×100 μm.

The light-emitting region, and/or the LED, may alternatively have lateral dimensions (width and length) of less than 100 μm. In this case, the LED may be termed a “micro-LED”. The micro-LED may preferably have lateral dimensions of less than 80 μm, or 70 μm, or 60 μm, or 50 μm or 30 μm, or 25 μm, or 20 μm, or 15 μm or 10 μm, or 5 μm or 3 μm or 2 μm.

In preferred embodiments, the micro-LED may be square or circular or square with circular corners and have dimensions such as 75 μm×75 μm, 50 μm×50 μm, 40 μm×40 μm, 30μm×30 μm, 25 μm×25 μm, 20 μm×20 μm or 10 μm×10 μm, or 5 μm×5 μm, or 2 μm×2 μm, or 1 μm×1 μm, or 500 nm×500 nm or smaller.

The light-emitting region, and/or the LED, may alternatively have lateral dimensions (width and length) of less than 1 μm. In this case, the LED may be termed a “nano-LED”. The nano-LED may preferably have lateral dimensions of less than or 500 nm, or 200 nm, or 100 nm, or 50 nm.

The LEDs may circular, triangle, rectangular, square, oval, diamond, hexagonal, pentagonal, and any combination of these shapes. In the case of irregular-shapes of pixel design, at least one dimension should fall within the dimensions defined above in order for the LEDs to be classed as mini-or micro-LEDs. For example the width or diameter of the LEDs are preferably less than 100 μm so that the LEDs are classed as micro-LEDs.

The porous layer may form an active component of the semiconductor device. The porous layer may form an optical component of the semiconductor device, for example in which the porous layer acts to scatter, reflect or transmit optical signals or optical emissions into or out of the semiconductor device. The porous layer may be configured to form an optical element such as a grating or a plurality of cones.

The porous layer may alternatively form a passive component of the semiconductor device. The porous layer may for example act as a compliant layer or a support layer for preventing cracking of the semiconductor device, or for strain management. The porous layer may act as an etch-stop layer during further device processing steps.

### BRIEF DESCRIPTION OF THE DRAWINGS

Embodiments of the invention will now be described with reference to the figures, in which:

FIG. 1A is a schematic side-on cross-section of a conventional semiconductor structure;

FIG. 1B is a schematic side-on cross-section of a semiconductor structure comprising a porous layer of semiconductor material positioned between the substrate and the semiconductor device;

FIG. 1C is a schematic side-on cross-section of a semiconductor structure comprising a porous layer of semiconductor material positioned between the substrate and the semiconductor device, and a buffer layer between the porous layer and the substrate;

FIGS. 2A-2C are schematic side-on cross-sections illustrating a semiconductor device being separated from a substrate using laser lift-off, according to a first embodiment of the present invention;

FIGS. 3A-3C are schematic side-on cross-sections illustrating a semiconductor device being separated from a substrate using laser lift-off, according to a second embodiment of the present invention;

FIGS. 4A-4C are schematic side-on cross-sections illustrating a semiconductor device being separated from a substrate using ion-implantation, according to a third embodiment of the present invention;

FIGS. 5A-5C are schematic side-on cross-sections illustrating a semiconductor device being separated from a substrate using a thermal gradient, according to a fourth embodiment of the present invention.

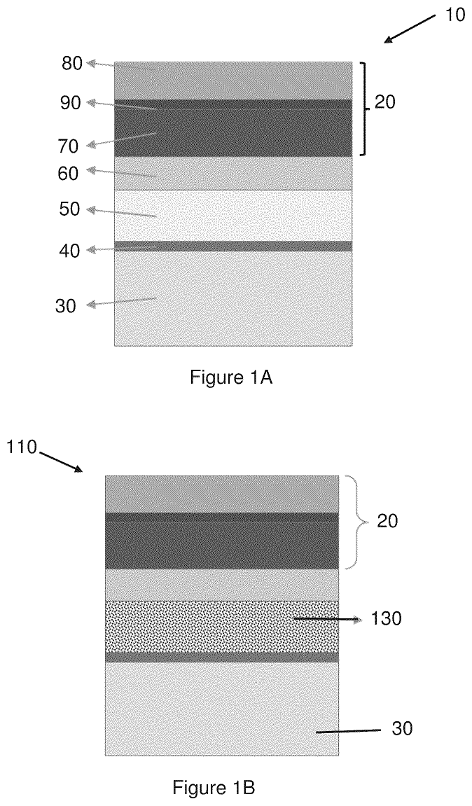

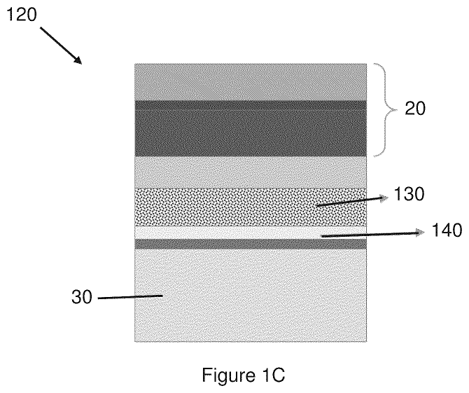

FIG. 1A illustrates a layered semiconductor structure 10 in which a conventional semiconductor device structure 20 is overgrown on a semiconductor substrate 30.

The semiconductor structure 10 is formed by epitaxial deposition of layers of semiconductor material on top of the semiconductor substrate 30. The substrate may be a conventional wafer of Silicon, Sapphire, SiC, GaN, or β-Ga2O3

Moving sequentially upwards from the substrate 30 in order of epitaxial growth, the semiconductor structure 10 contains:
a buffer layer 40, which may for example be a layer of undoped GaN;
a layer of undoped GaN 50, which may act as a further buffer layer;
a layer of NID-GaN (non-intentionally doped GaN) 60;
a semiconductor device structure 20 which in the illustrated embodiment is an LED consisting of two layers of doped GaN 70, 80 arranged around a light-emitting region 90 containing a multiple quantum well (MQW).

FIG. 1B illustrates a semiconductor structure 110 usable in the present invention, which corresponds to the structure shown in FIG. 1A, except that the layer of undoped GaN 50 is instead a porous layer 130 of GaN. The porous layer of GaN is preferably an n-doped layer of GaN which is electrochemically porosified using a known technique. The porous region may be provided by epitaxially growing an n-doped region of III-nitride material and then an undoped layer of III-nitride material, and porosifying the n-doped region using the porosification process as set out in international patent applications PCT/GB2017/052895 (published as WO2019/063957) and PCT/GB2019/050213 (published as WO2019/145728).

This porosification leads to strain relaxation in the crystal lattice, which means that subsequent overgrowth of further semiconductor layers benefit from reduced compressive strain in their lattices.

The porous region may comprise one or more layers one or more III-nitride materials, and may have a range of thicknesses. In preferred embodiments, the porous region may for example comprise GaN and/or InGaN.

A variety of semiconductor device structures 20 may be overgrown over the porous layer, but a schematic LED device structure is used in the Figures for the purpose of illustration. device is a high electron mobility transistor (HEMT), a radio-frequency (RF) device, an LED, or a mini-LED, or a micro-LED, or a nano-LED.

FIG. 1C illustrates a semiconductor structure 120 usable in the present invention, which corresponds to the structure shown in FIG. 1B, except that the structure 120 contains an additional buffer layer 140 of undoped GaN. The buffer layer 140 is positioned between the porous layer 130 and the substrate 30. The buffer layer 140 is essential for only some embodiments of the invention, as described above.

In order to prepare the semiconductor structures of FIGS. 1B and 1C for separation from their substrates 20, the uppermost layer of the semiconductor device structures 20 is bonded to a carrier wafer 150 by a bonding layer 160. This helps to ensure that the semiconductor devices are mechanically supported during cleaving and separation, and allows them to be securely removed from the substrate after the cleaving has taken place. The carrier wafer may be a temporary carrier wafer, or alternatively the carrier wafer may be a substrate comprising control circuitry for processing into a device.

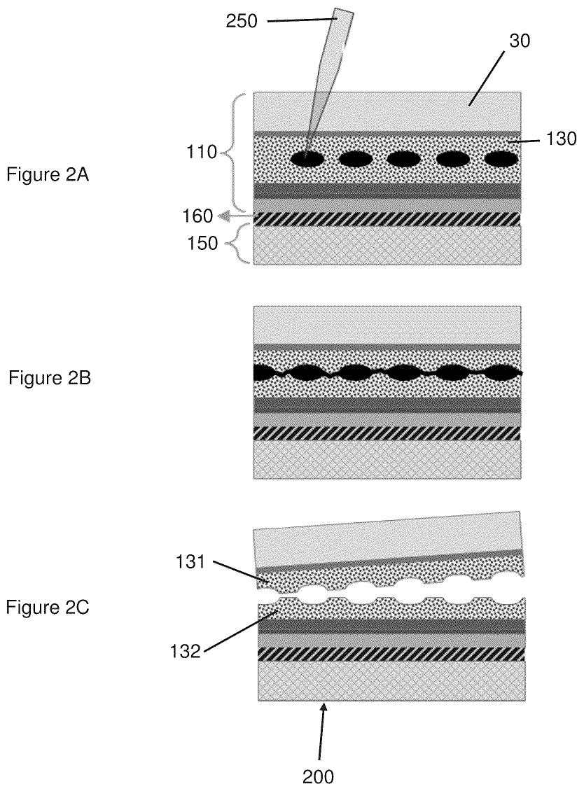

### FIGS. 2A-C—Laser Lift-Off at Porous Layer

FIGS. 2A-2C illustrate a first preferred embodiment of the invention in which the separation of the semiconductor device structure 20 from the substrate 30 is performed using laser lift-off (LLO) in the porous layer 130.

As shown in FIG. 2A, a laser 250 is focused at a depth in the semiconductor structure which coincides with the depth of the porous layer 130. The laser then melts semiconductor material where it is focused in the porous layer 130, creating a series of holes 160 at different positions throughout the porous layer. This weakens the entire porous layer 130, so that the combined effect of many melted spots makes the entire layer into a weakened zone of the structure. The evolution of nitrogen gas where the porous GaN is melted creates pressure which eventually cleaves the structure by fracturing the porous layer as shown in FIG. 2B.

Once the semiconductor structure 110 has been cleaved by the fracture extending through the porous layer 130, a first portion 131 of the porous layer remains attached to the substrate 30, while a second portion 132 of the porous layer remains attached to the post-separation semiconductor structure 200 containing the semiconductor device 20 and the carrier wafer 150, as shown in FIG. 2C.

As the cleaving process typically forms a non-uniform crack or fracture through the semiconductor structure, the cleaved surfaces are typically rough after the structure has been separated. It is typically desirable, therefore, to flatten the cleaved surfaces by chemical-mechanical polishing (CMP) or etching prior to further processing. The first and second porous regions 131, 132 may either be removed entirely by CMP or etching, or they may simply be smoothed to remove roughness from the exposed cleaved surfaces.

The flattened substrate may then be re-used as a template for overgrowth of semiconductor material, and the semiconductor device 20 may be further processed into an end device.

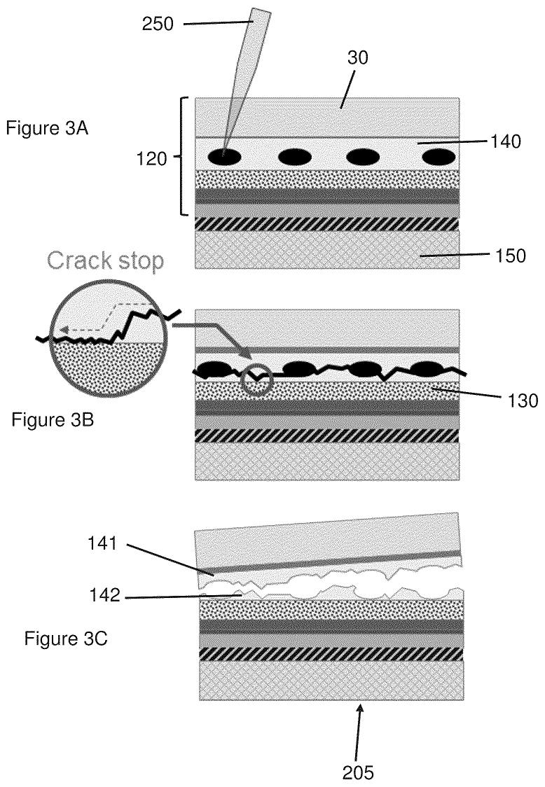

### FIGS. 3A-B—Laser Lift-Off at Porous Layer

In a second preferred embodiment of the invention, the weakened zone is created in the buffer layer 140 of the semiconductor structure 120 by laser lift-off.

As shown in FIG. 3A, in this embodiment the laser 250 is focused in the buffer layer 140, for example at an interface between the buffer layer 140 and the substrate 30. The laser then melts the undoped GaN of the buffer layer 140 at a series of locations across the buffer layer 140, weakening the buffer layer and generating nitrogen gas which creates a fracture to cleave the buffer layer 140 as shown in FIG. 3B.

In this embodiment, the porous layer advantageously acts as a “crack-stop” layer which confines the fracture to the buffer layer and prevents the fracture from propagating vertically through the semiconductor structure into the active layers of the device structure.

In this embodiment, the porous layer remains attached to the semiconductor device after separation, and the porous layer may act as a compliant layer which manages the stress on the semiconductor device after separation from the substrate.

As shown in FIG. 3C, after cleaving a first portion 141 of the buffer layer 140 remains attached to the substrate 30, while a second portion 142 of the buffer layer remains attached to the post-separation semiconductor structure 205 now containing the porous layer 130, the semiconductor device 20 and the carrier wafer 150.

The separated parts of the semiconductor structure 120 may be further processed as described above in relation to FIGS. 2A-2C.

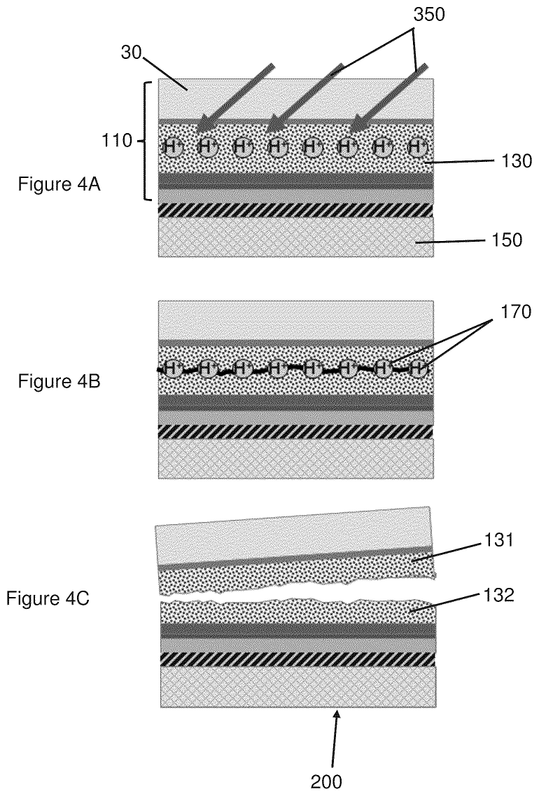

### FIGS. 4A-C—Ion-Implantation to Porous Layer

In a third preferred embodiment of the present invention, the weakened zone is created in the porous layer 130 by implanting dopant ions 170 into the porous layer of semiconductor material. The implanted ions create an additional level of atomic disorder in the porous layer of semiconductor material by displacing some of the atoms in the crystal structure of the porous layer. This may advantageously weaken the porous layer, making it more easily and uniformly cleavable.

The dopant ions may preferably be selected from the list: H+, N+, Ga+, O+, Si+, Mg+, C+.

As shown in FIG. 4A, dopant ions are implanted into the porous layer 130 by bombarding the porous layer of the semiconductor structure with an ion beam 350 (high energy or low energy-keV-MeV). Alternative methods of ion implantation are also known in the art and may be used to implant dopant ions into the porous layer to create the weakened zone.

The dopant ions create atomic disorder in the porous layer, weakening the porous layer 130 so that it fractures through the ion-implanted porous layer as shown in FIG. 4B.

Once the semiconductor structure 110 has been cleaved by the fracture extending through the porous layer 130, a first portion 131 of the porous layer remains attached to the substrate 30, while a second portion 132 of the porous layer remains attached to the post-separation semiconductor structure 200 containing the semiconductor device 20 and the carrier wafer 150, as shown in FIG. 4C.

The separated parts of the semiconductor structure 110 may be further processed as described above in relation to FIGS. 2A-2C.

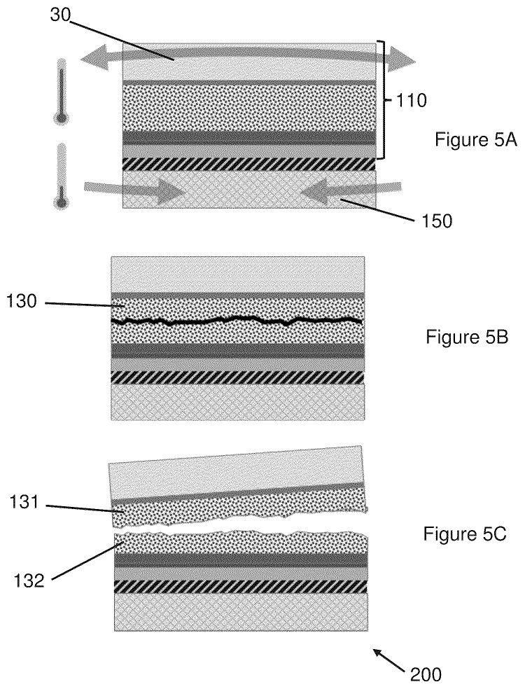

### FIGS. 5A-C—Thermal Gradient

In a fourth preferred embodiment of the present invention, the weakened zone is created in the porous layer by creating a thermal gradient across the porous layer, the direction of the thermal gradient being orthogonal to the plane of the porous layer.

As shown in FIG. 5A, a thermal gradient is created by applying a temperature difference across the semiconductor structure 110, by holding the substrate 30 at a hotter temperature than the carrier wafer 150. By making one side of the porous layer hotter than the other, the semiconductor material on the hotter side may be caused to expand, while the semiconductor material on the cooler side may be caused to contract. This difference in thermal expansion and contraction across the porous layer may in turn create a stress in the porous layer which initiates a fracture (shown in FIG. 5B) that propagates through the porous layer to cleave the semiconductor structure.

Once the semiconductor structure 110 has been cleaved by the fracture extending through the porous layer 130, a first portion 131 of the porous layer remains attached to the substrate 30, while a second portion 132 of the porous layer remains attached to the semiconductor device 20 and the carrier wafer 150, as shown in FIG. 5C.

The separated parts of the semiconductor structure 110 may be further processed as described above in relation to FIGS. 2A-2C.

After separation, post-separation semiconductor structures 200 processed using these methods are identifiable thanks to the semiconductor device 20 being bonded to a carrier wafer 150, with the active region of the semiconductor device positioned between the porous layer 130 and the carrier wafer 150.

If the semiconductor structure 110 has been cleaved through the porous layer 130, the first portion 131 of the porous layer may remain connected to the semiconductor device and form the outermost surface of the post-separation semiconductor structure 200.

If the semiconductor structure 120 has been cleaved through a non-porous buffer layer between the porous layer and the substrate, the porous layer may remain connected to the semiconductor device, and one or more buffer layers 140 may form the outermost surface of the resulting semiconductor structure. Alternatively, if the cleaved buffer layer 140 has been removed during cleaving and optionally during subsequent etching/polishing, the porous layer may form the new outermost surface of the post-separation semiconductor structure 200.

1. A method of separating a semiconductor device from a substrate, the method comprising the steps of:
providing a semiconductor structure comprising a semiconductor device, a substrate, and a porous layer of semiconductor material between the semiconductor structure and the substrate;
creating a weakened zone in the semiconductor structure between the semiconductor device and the substrate;
cleaving the semiconductor structure along the weakened zone; and
separating the semiconductor device from the substrate;
in which the weakened zone is created in the porous layer of semiconductor material, or in a buffer layer of semiconductor material positioned between the substrate and the porous layer.

2. The method of claim 1, in which the weakened zone comprises a weakened layer which extends laterally through a layer of the semiconductor structure.

3. The method of claim 1 or 2, in which the weakened zone is created by laser lift-off.

4. The method of claim 3, comprising the step of directing a laser into the semiconductor structure through the substrate, focusing the laser at a predetermined depth in the semiconductor structure, and melting semiconductor material at the focal point of the laser.

5. The method of claim 4, comprising the step of focusing the laser in the porous layer, and melting semiconductor material contained in the porous layer of semiconductor material.

6. The method of claim 4, comprising the step of focusing the laser at an interface between the porous layer and the substrate, and melting semiconductor material at the interface between the porous layer and the substrate.

7. The method of claim 4, comprising the step of focusing the laser at an interface between the porous layer and a buffer layer of semiconductor material that is positioned between the substrate and the porous layer.

8. The method of claim 4, comprising the step of focusing the laser in the buffer layer of semiconductor material that is positioned between the substrate and the porous layer.

9. The method of claim 4, comprising the step of focusing the laser at an interface between the buffer layer and the substrate.

10. The method of claim 7, 8 or 9, in which the buffer layer is a layer of undoped semiconductor material positioned between the substrate and the porous layer, preferably in which the buffer layer is positioned adjacent to the substrate.

11. The method of any of claims 7 to 10, in which cleaving the semiconductor structure along the weakened zone creates a fracture in the buffer layer, and in which the porous layer confines the fracture to the buffer layer and prevents the fracture from propagating vertically through the semiconductor structure.

12. The method of claim 1 or 2, in which the weakened zone is created by implanting dopant ions into a layer of the semiconductor structure.

13. The method of claim 12, in which the dopant ions are selected from the list: H+, N+, Ga+, O+, Si+, Mg+, C+.

14. The method of claim 12 or 13, in which the method comprises the step of implanting dopant ions by ion bombardment.

15. The method of claim 12, 13 or 14, in which dopant ions are implanted into the porous layer of the semiconductor structure.

16. The method of claim 12, 13 or 14, in which dopant ions are implanted into a buffer layer positioned between the substrate and the porous layer.

17. The method of any of claims 12 to 17, in which dopant ions are implanted into the porous layer before the semiconductor device has been formed on the semiconductor structure.

18. The method of claim 1 or 2, in which the weakened zone is created in the porous layer by creating a thermal gradient across the porous layer, the direction of the thermal gradient being orthogonal to the plane of the porous layer.

19. The method of claim 18, in which a thermal gradient is created by applying a temperature difference between the semiconductor device and the substrate.

20. The method of claim 18 or 19, comprising the step of applying a thermal gradient of at least 50 degrees centigrade per um between the semiconductor device and the substrate, or at least 60, or 70, or 80, or 90, or 100 degrees centigrade per um between the semiconductor device and the substrate.

21. The method of claim 18, 19 or 20, comprising the step of applying a thermal gradient of at least 50 degrees centigrade between the semiconductor device and the substrate, or at least 60, or 70, or 80, or 90, or 100 degrees centigrade between the semiconductor device and the substrate 22. The method of any preceding claim, in which the semiconductor device is bonded to a carrier wafer prior to the steps of creating a weakened zone and cleaving the semiconductor structure, so that the semiconductor device remains bonded to the carrier wafer when the semiconductor device is separated from the substrate.

23. The method of any preceding claim, in which the step of cleaving creates a cleaved surface connected to the semiconductor device, the method additionally comprising the step of flattening the cleaved surface of the semiconductor device after the semiconductor device has been separated from the substrate.

24. The method of any preceding claim, in which the step of cleaving creates a cleaved surface connected to the substrate, the method additionally comprising the step of flattening the cleaved surface connected to the substrate.

25. The method of claim 21, comprising the step of re-using the flattened substrate as a template for overgrowth of semiconductor material.

26. The method of any of claims 20 to 22, in which the cleaved surface is flattened by chemical-mechanical (CMP) polishing or etching.

27. The method of any preceding claim, in which the porous layer is a layer of porous III-nitride material, for example a porous layer of GaN, InGaN, AlGaN, or InAlGaN.

28. The method of any preceding claim, in which the semiconductor device is a high electron mobility transistor (HEMT).

29. The method of any of claims 1 to 24, in which the semiconductor device is a radio-frequency (RF) device) 30. The method of any of claims 1 to 24, in which the semiconductor device is an LED, or a mini-LED, or a micro-LED, or a nano-LED.

31. A method of separating a semiconductor device from a substrate, the method comprising the steps of:
providing a semiconductor structure comprising a semiconductor device, a substrate, and a porous layer of semiconductor material between the semiconductor structure and the substrate;
bonding the semiconductor structure to a carrier wafer so that the semiconductor device and the porous layer are positioned between the carrier wafer and the substrate; and
removing the substrate from the semiconductor structure by polishing, lapping, thinning, wet etching or dry etching.

32. A method according to claim 31, in which the substrate is a silicon substrate.

33. A semiconductor structure comprising a porous layer of semiconductor material and a semiconductor device bonded to a carrier wafer, in which the semiconductor device is positioned between the porous layer and the carrier wafer.

34. The semiconductor structure of claim 33, in which the semiconductor device comprises an active region, for example a light-emitting active region, which is positioned between the porous layer and the carrier wafer.

35. The semiconductor structure of claim 33 or 34, in which the porous layer of semiconductor material forms an outermost surface of the structure, on the opposite side of the active region from the carrier wafer.

36. The semiconductor structure of claim 33 or 34, in which a buffer layer of semiconductor material may form the outermost surface of the structure, with the porous layer being positioned between the outermost buffer layer and the active region of the semiconductor device.

37. The semiconductor structure of any of claims 33 to 36, in which the semiconductor device is a high electron mobility transistor (HEMT).

38. The semiconductor structure of any of claims 33 to 36, in which the semiconductor device is a radio-frequency (RF) device.

39. The semiconductor structure of any of claims 33 to 36, in which the semiconductor device is an LED, or a mini-LED, or a micro-LED, or a nano-LED.

40. The semiconductor structure of any of claims 33 to 39, in which the porous layer forms an active component of the semiconductor device.

41. The semiconductor structure of claim 40, in which the porous layer forms an optical component of the semiconductor device, for example in which the porous layer acts to scatter, reflect or transmit optical signals or optical emissions into or out of the semiconductor device.

42. The semiconductor structure of claim 40 or claim 41, in which the porous layer is configured to form an optical element such as a grating or a plurality of cones.

43. The semiconductor structure of any of claims 33 to 39, in which the porous layer forms a passive component of the semiconductor device.

44. The semiconductor structure of claim 43, in which the porous layer acts as a compliant layer or a support layer for preventing cracking of the semiconductor device.

45. The semiconductor structure of claim 43, in which the porous layer acts as an etch-stop layer.
